(19) United States
(12) Patent Application Publication
(10) Pub. No.: US 2008/0267076 A1
(43) Pub. Date: Oct. 30, 2008

(54) SYSTEM AND APPARATUS FOR MAINTAINING A COMMUNICATION SYSTEM

(75) Inventors: ERIAN LAPERI, WENTZVILLE, MO (US); BENNETT SEYER, BALLWIN, MO (US); GEOFFREY HODGES, RAYMORE, MO (US); THOMAS C. STOVALL, KINGWOOD, TX (US); MICHAEL J. ANDERSON, O FALLON, MO (US); JOEL PALMER, ST. LOUIS, MO (US); TIMOTHY L. LAFAVER, BALLWIN, MO (US); WILLIAM J. DURANT, SAN ANTONIO, TX (US); JEREMY A. DILKS, EAST ALTON, IL (US)

Correspondence Address: AKERMAN SENTERFITT, P.O. BOX 3188, WEST PALM BEACH, FL, 33402-3188, US

(73) Assignee: AT&T KNOWLEDGE VENTURES, L.P., RENO, NV (US)

(21) Appl. No.: 11/742,140

(22) Filed: Apr. 30, 2007

(51) Int. Cl. G01R 31/08; G06F 11/00; G08C 15/00; H04L 1/00

(52) U.S. Cl. 370/242

(57) ABSTRACT

A system and apparatus for maintaining a communication system is disclosed. An apparatus that incorporates teachings of the present disclosure may include, for example, a computer-readable storage medium in a maintenance server of a communication system, comprising computer instructions for monitoring for installed components in interconnected Digital Subscriber Line (DSL) networks of the communication system based at least in part on provisioning records for each of the interconnected DSL networks, filtering telemetry and maintenance data associated with the installed components in the interconnected DSL networks according to criteria comprising actual criteria and predictive criteria, monitoring for a fault in the installed components based at least in part on the telemetry and maintenance data associated with the actual criteria, and predicting a potential fault in the installed components based at least in part on the telemetry and maintenance data associated with the predictive criteria. Additional embodiments are disclosed.

### FIELD OF THE DISCLOSURE

The present disclosure relates generally to interconnected communication networks, and more specifically to a system and apparatus for maintaining a communication system.

### BACKGROUND

Digital Subscriber Line (DSL) services are generally provided to consumers by two distinct service providers, a local DSL network provider and an Internet Service Provider (ISP). In general, the local DSL network provider is a local phone company. Internet access is generally provided to customers accessing the local DSL network by one or more separate ISP's having access to one or more local DSL networks. As a result of this arrangement, ISP's can be limited in preventing performance degradation and addressing performance issues of customers that may be due to problems in the local DSL networks.

In other instances the DSL network provider and the ISP are managed by the same service provider. In this instance, the service provider may have more control and visibility into in managing aspects of the DSL networks. Nonetheless, with a large number of field repairs and historical faults in the cabling distribution of DSL networks, it can be challenging to maintain a desired level of performance in said networks.

Similar observations can be made of other wired communication systems such as those that distribute coaxial cable and fiber to residences and commercial enterprises.

A need therefore arises for a system and apparatus for maintaining a communication system.

### BRIEF DESCRIPTION OF THE DRAWINGS

FIG. 1 depicts an exemplary embodiment of a communication system;

FIG. 2 depicts an exemplary method operating in the communication system; and

FIG. 3 depicts an exemplary diagrammatic representation of a machine in the form of a computer system within which a set of instructions, when executed, may cause the machine to perform any one or more of the methodologies disclosed herein.

### DETAILED DESCRIPTION

Embodiments in accordance with the present disclosure provide a system and apparatus for maintaining a communication system.

In a first embodiment of the present disclosure, a network proxy of a communication system can include a controller element to monitor for installed components in one or more interconnected Digital Subscriber Line (DSL) networks of the communication system based at least in part on provisioning records for each of the interconnected DSL networks, obtain telemetry data from at least one of the installed components in the interconnected DSL networks, obtain maintenance data based at least in part on repair records associated with the installed components in the interconnected DSL networks, filter the telemetry and maintenance data according to criteria comprising actual criteria and predictive criteria, determine one or more common components associated with the telemetry and maintenance data, monitor for a fault in the one or more common components based at least in part on the telemetry and maintenance data associated with the actual criteria, and predict a potential fault in the one or more common components based at least in part on the telemetry and maintenance data associated with the predictive criteria.

In a second embodiment of the present disclosure, a network element coupled to one or more interconnected Digital Subscriber Line (DSL) networks of a communication system can include a controller to receive fault data from a network proxy of the communication system, where the fault data can be representative of a potential fault in a component of a plurality of components of the interconnected DSL networks, and test the component for the potential fault based at least in part on telemetry data and maintenance data associated with the component, where the plurality of components is identified from provisioning records for each of the interconnected DSL networks, where the telemetry data is obtained from at least one of the plurality of components, and where the maintenance data is generated from repair records associated with the plurality of components.

In a third embodiment of the present disclosure, a computer-readable storage medium in a maintenance server of a communication system can include computer instructions for monitoring for installed components in interconnected cable networks of the communication system based at least in part on provisioning records for each of the interconnected cable networks, filtering telemetry and maintenance data associated with the installed components in the interconnected cable networks according to criteria comprising actual criteria and predictive criteria, monitoring for a fault in the installed components based at least in part on the telemetry and maintenance data associated with the actual criteria, and predicting a potential fault in the installed components based at least in part on the telemetry and maintenance data associated with the predictive criteria.

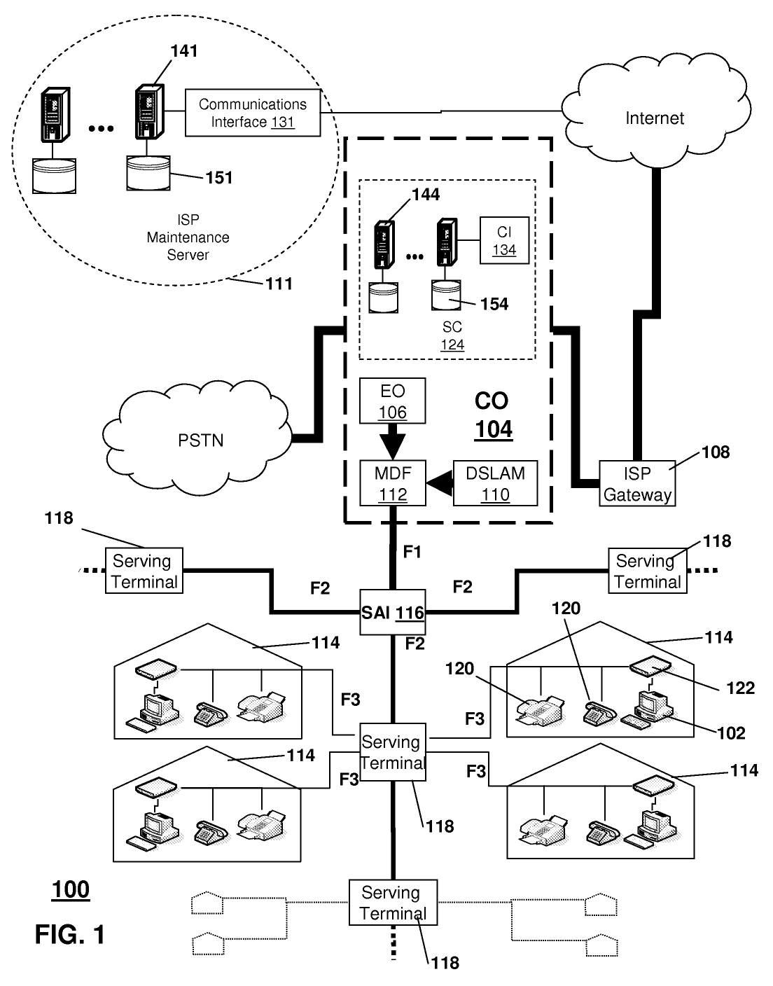

FIG. 1 depicts an exemplary embodiment of a communication system 100 having portions that can be configured for managing and providing Digital Subscriber Line (DSL) services to one or more computing devices 102. The system 100 can comprise a DSL backbone and can have at least one central office (CO) 104 providing voice services via a local network infrastructure coupled to a public switched telephone network (PSTN) via an end office (EO) switch center 106 of the CO 104. The CO 104 can also provide data and/or video services to voice customers via one or more network elements, such as digital subscriber line access multiplexers (DSLAMs) 110, having access to gateway servers 108 of one or more Internet Service Providers (ISPs). In one embodiment, the communication system 100 can operate as an IP Multimedia Subsystem (IMS) conforming in part to protocols defined by standards bodies such as 3GPP (Third Generation Partnership Protocol). In the system 100, operation of the CO 104 and the local network infrastructure can be monitored and analyzed by a maintenance server or network proxy 111 of the ISP.

The maintenance server 111 operating in the system 100 can operate as a single computing system or as centralized or decentralized computing devices. The maintenance server 111 can comprise a communications interface 131, a controller element 141 and a memory or mass storage system 151. The communications interface 131 can utilize common networking technologies (e.g., LAN, WLAN, TCP/IP, etc.) to manage data communications with the CO 104. The controller element 141 can utilize common computing technologies (e.g., desktop computer, server, etc.) to manage use of available processing resources of the maintenance server 111 for executing one or more processes and to manage operation of the mass storage system 151 and the communications interface 131. The mass storage system 151 can utilize common storage technologies (e.g., hard disk drives, flash memory, etc.) to store data in one or more databases.

The CO 104 can be configured to combine voice content from the EO switch center 106 and data content from the DSLAM 110 at a main distribution frame (MDF) 112 in order to distribute voice and data content to commercial and/or residential buildings 114. For example, the combined content at the MDF 112 can first be distributed via a feeder cable (F1) to one or more service access interfaces (SAI's) 116 in local areas (e.g., neighborhoods) serviced by the CO 104. This combined content at the SAI 116 can be distributed via one or more distribution cables (F2) to a local group of buildings serviced by a serving terminal or pedestal 118. Subsequently, the combined content at the serving terminal 118 can be distributed to individual buildings via one or more cable drops (F3). The cable drops (F3) can be tied into the telephony distribution system of the building 114, which in turn distributes the combined content to telephony devices 120 (e.g., analog phones and fax machines) and/or computing devices 102 (e.g., local servers, desktop computers, laptop computers) via one or more DSL modems 122. The present disclosure also contemplates other routings and configurations between the CO 104 and the one or more buildings 114 to deliver the voice, video and/or data services described herein.

The CO 104 can also include a service center (SC) 124 for managing operations and information for the local network. The SC 124 can operate as a single computing system or as centralized or decentralized computing devices. For example, where the local network infrastructure supports both voice and data content from the CO 104, the SC 124 can comprise order management systems, IP Multimedia Subsystems, customer premise equipment (CPE) provisioning and monitoring systems, local network infrastructure provisioning and monitoring systems, repair and maintenance systems, voicemail systems, address book systems, and so on. The present disclosure also contemplates other systems, devices and techniques being utilized for managing operations and information of the local network in combination with, and/or independent of, the SC 124.

The SC 124 operating in the CO 104 can comprise a communications interface (CI) 134, a controller element 144 and a memory or mass storage system 154. The communications interface 134 can utilize common networking technologies (e.g., LAN, WLAN, TCP/IP, etc.) to manage data communications with other network elements, including the maintenance server 111. The controller element 144 can utilize common computing technologies (e.g., desktop computer, server, etc.) to manage use of available processing resources of the SC 124 for executing one or more processes for managing operations and information for the CO 104 and components in the local network, as well as managing operation of the mass storage system 154 and the communications interface 134. The mass storage system 154 can utilize common storage technologies (e.g., hard disk drives, flash memory, etc.) to store data in one or more databases.

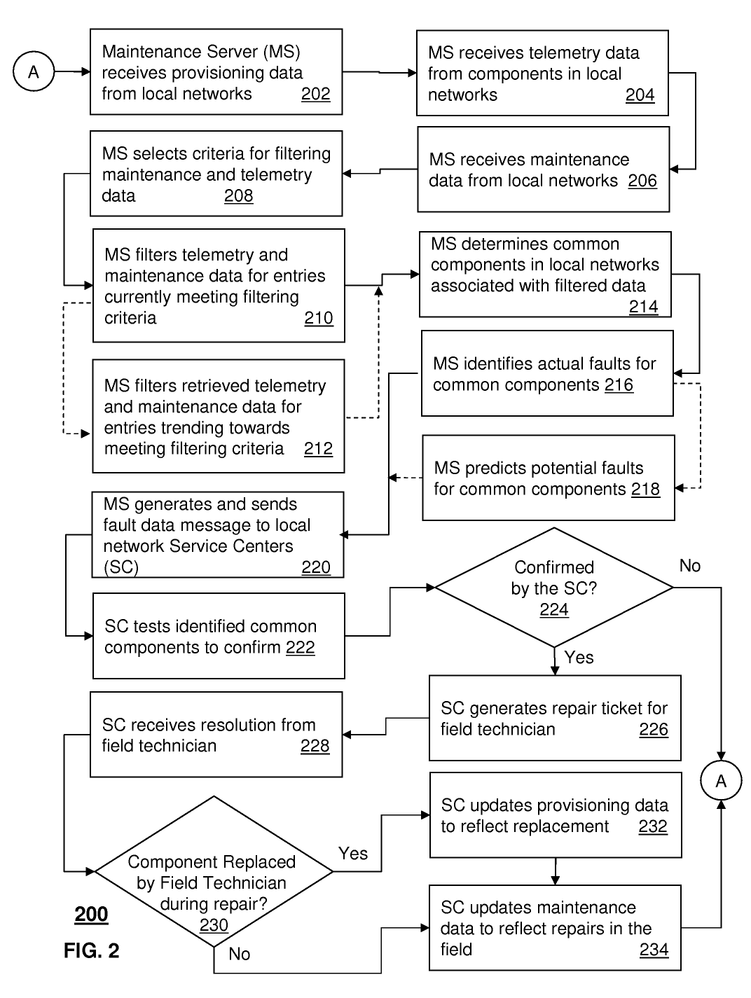

FIG. 2 depicts an exemplary method 200 operating in portions of the communication system 100. Method 200 has variants as depicted by the dashed lines. It would be apparent to an artisan with ordinary skill in the art that other embodiments not depicted in FIG. 2 are possible without departing from the scope of the claims described below.

Method 200 begins with step 202 in which the network proxy or maintenance server 111 monitors for installed components in one or more local networks. In some instances, the maintenance server 111 can receive provisioning information located in a provisioning system for the CO 104. For example, the CO 104 can be configured to transmit current provisioning information from a customer premises equipment (CPE) provisioning system or a local network infrastructure provisioning system to the maintenance server 111. Alternatively or in combination, the maintenance server 111 can remotely access one or more other provisioning systems, such as databases of third-party vendors, for the CO 104.

The provisioning information can include an identification of the components installed in, or otherwise operably coupled to, the local network. The provisioning information can also include information on how the components are configured, interconnected, and/or installed. For example, provisioning information can include cable/pair records associated with components. In another example, the provisioning information can indicate the type of installation for the network component, such as an aerial or underground installation. The provisioning information can also include a location for the various components, such as a street or neighborhood address for a SAI 116, a serving terminal 118, or any other installed components in the local network.

Subsequently or in combination with step 202, the maintenance server 111 in step 204 can receive telemetry data associated with the one or more components installed in the local networks. For example, one or more network components can be configured to generate performance data such as current bit rates, maximum attainable bit rates, noise margins, errors detected, signal attenuation, bit rate stacking errors, detected frequency interference, line capacity, latency, and so on. Additionally, data from mechanical line testing can also be received by the maintenance server 111, including data generated by the CO 104, such as metallic loop data. In some instances, the generated data can be collected by the CO 104 and transmitted to the maintenance server 111 by the CO. In other instances, the components of the local network can be configured to directly transmit telemetry data to the maintenance server 111. For example, one or more components can be configured to communicate over a broadband connection directly with the maintenance server 111. In one embodiment, the data can be obtained by way of polling of the one or more components by the network server 111 and/or by another network element. In another embodiment, one or more of the components can provide the data in real time to the maintenance server 111.

Subsequently, or in combination with steps 202 and 204, the maintenance server 111 in step 206 can receive maintenance and repair information (maintenance data) from the local networks. The maintenance data received by the maintenance server 111 can be associated with various aspects of the local network, including the one or more components. For example, the maintenance data can include a trouble report history for one or more components, for particular geographic areas, for particular grades of services provided over the local network, and/or for POTS services. The trouble report can include failures that have been detected by the CO 104, reported by customers, or both. Additionally, the trouble report history can include trouble history regarding data services, voice services, or both. In another example, the maintenance data can include a maintenance log for one or more components. The log can further include a preventive maintenance history, a repair history, or a replacement history for one or more components or areas of service. Other types of records not described herein that can provide other maintenance and repair information of the local network can also be applied to the present disclosure for gathering the maintenance data.

Subsequently or in combination with steps 202-206, the maintenance server 111 in step 208 can select one or more criterion to use for filtering the maintenance and telemetry data. In some instances the criteria can comprise performance data generated by the local network. For example, the data can be filtered to include only data showing entries exceeding or falling below a threshold value or exceeding a tolerance limit, such as an attenuation value or a bit rate value. In another example, the data can be filtered to include only data showing repeated failures, such as repeated time periods with a large number of code violations.

Maintenance records can also be used to define the criteria. For example, the data can be filtered to include only data showing a large number of entries in maintenance records, such as a circuit having two or more repairs within a specific length of time. Additionally, multiple filters can be used to identify multiple types of problems in the local networks.

Maintenance server 111 can utilize information from multiple networks to determine existing and potential points of trouble in other networks, and is not limited to monitoring individual component failures in one or more local networks. Maintenance server 111 can analyze current data based on past and present patterns, including patterns of irregularities and failures, in multiple networks. For example, the maintenance server 111 can monitor and analyze fault information in a local network to determine patterns of similar faults in other networks. If these similar faults are associated with known problems in other networks, the network server can use this information to proactively discover possible issues before customers are affected. In the present context, a fault can mean a bonding fault, a grounding fault, a metallic fault, a bridge tap fault, an electromagnetic interference fault, or any other type of fault that can adversely affect services supplied to a residential or commercial enterprise 114.

Values, thresholds, and tolerances which are utilized as filtering criteria can be selected in several ways. For example, the filtering criteria can be based on selected threshold and tolerance values that define a minimum quality of service that an ISP wishes to provide at all times. The values associated with the filtering criteria can be based on historical data from other portions of the local network or other local networks that have resulted in failures in the past. For instance, if an average number of errors in a component in several networks typically results in a failure, this average number can be used as a threshold value for other networks.

Once the filtering criteria are selected, the maintenance server 111 can filter the maintenance and telemetry data in step 210. In one embodiment, maintenance server 111 can predict possible faults in the one or more components of the local networks. Subsequently or in combination with step 210, the maintenance server 111 in step 212 can determine if a current trend in the data is likely to result in a value meeting a criteria. For example, a steadily decreasing bit rate, although not currently falling below a minimum threshold value, can be included in the filtered data as indicative of a potential fault. Similarly, if a number of detected errors or repair requests have not yet exceeded a threshold value, but the current rate is indicative of exceeding the value within a specified time period, the data can also be included in the filtered data as indicative of a potential fault.

After the maintenance server 111 filters the maintenance and telemetry data, the maintenance server in step 214 can access the provisioning information, and determine the common components of the local networks that are associated with the filtered data. Afterwards, the maintenance server 111 in step 216 can identify actual faults associated with the common components that were identified in step 214. Subsequently or in combination with step 216, the maintenance server 111 in step 218 can predict potential faults associated with the common components. For example, a maintenance server 111 can associate a potential or an actual fault in a single common component, such as a particular SAI 116, a particular serving terminal 118, or particular cables or drops (e.g., F1, F2, or F3). In such instances, the maintenance server 111 can determine that a large amount of maintenance and telemetry data meeting one or more failure criteria is associated with the common component, and is associated with some type of actual fault. Similarly, a large amount of maintenance and telemetry data that is trending towards meeting one or more failure criteria can be associated with some type of potential fault in the common component. Additionally, a combination of data meeting criteria and data trending towards meeting one or more criteria can be used to identify actual faults and/or predict potential faults in a common component. The common component can be a component coupled to or in communication with one or more other components of the local area networks. For example, the maintenance server 111 can determine that an F1, F2 or F3 cable, a SAI, and/or a serving terminal/pedestal is a common component that is upstream from a series of components which are reporting irregularities, errors and/or failures.

Once the common components have been associated with actual or potential faults in steps 216 and 218, the maintenance server in step 220 can generate and send a message to an SC 124 identifying faults and/or potential faults in the local network which is associated with the SC. The message can include an identification of the common components affected, the actual and potential faults discovered, individual components affected, or any combination thereof. By associating faults and/or potential faults with common components rather than with single components, possible systematic problems in the local networks can be identified and resolved prior to DSL ISP customers being affected.

In response to the message received, the SC 124 in step 222 can review and test one or more of the local network components to confirm the fault and/or potential fault identified in the message. For example, if a message indicates a specific bit rate failure in a common component, the SC 124 can review current bit rate data for the common component to determine whether the problem has already been resolved or whether a repair is needed. In another example, if the message indicates a potential problem in a common component not yet indicating an error, the SC 124 can be configured to test the common component or associated network elements to determine if a latent problem exists and/or if a repair will be required in the near future. If the SC 124 cannot confirm the fault and/or potential fault determined by the maintenance server in step 224, the SC 124 can continue to monitor for other messages from the maintenance server 111. If on the other hand, the SC 124 confirms the fault and/or potential fault determined by the maintenance server 111, the SC in step 226 can generate a trouble or repair ticket for a field technician to inspect and repair the components or associated network elements identified in the message from the maintenance server.

Once a field technician makes repairs to the one or more components identified in the repair ticket, resolution information can be submitted to the SC 124. For example, the field technician may enter resolution information via an access terminal for the SC 124 in step 228. Subsequently, the SC 124 in step 230 can review the resolution information to determine the action that took place, including replacement, removal, or addition of one or more components. If the SC 124 determines in step 230 that the resolution required a replacement, removal, or addition of a component, then the SC 124 in step 232 can update the provisioning data of the CO 104 to reflect changes in equipment. In step 234, the SC 124 can update the maintenance records to record the resolution of the fault and continue to monitor for further messages generated by the maintenance server 111. If on the other hand, the SC 124 determines in step 230 that the resolution did not require a replacement, removal, or addition of a component, then the SC 124 can update the maintenance records accordingly, as in step 234. The maintenance server 111 can continue to generate future messages by repeating steps 202-220 by including any updated information provided in steps 232 and 234.

Upon reviewing the aforementioned embodiments, it would be evident to an artisan with ordinary skill in the art that said embodiments can be modified, reduced, or enhanced without departing from the scope and spirit of the claims described below. For example, although the illustrated communication system 100 is typical for a copper line, central office (CO) based DSL network or an Asymmetric Digital Subscriber Line (ADSL), the method is also applicable to other DSL network configurations, such as remote terminal (RT) based DSL networks (e.g., VDSL or VHDSL (Very High Speed DSL)) and other fiber to the curb (FTTC) DSL networks. It should also be noted that the method can be applied to other cable networks such as coaxial cable network, and/or a fiber cable network distributed to a residence or commercial enterprise. In another example, one or more components included in the SC 124 can be located elsewhere in the CO 104 or at remote locations. In yet another example, the method 200 can be applied by not only the ISP directly accessed by the local network, but by upstream ISPs. In still another example, rather than receiving messages from the maintenance server 111, the SC 124 can be configured to request the maintenance server 111 to perform an analysis on demand. These are but a few examples of modifications that can be applied to the present disclosure without departing from the scope of the claims stated below. Accordingly, the reader is directed to the claims section for a fuller understanding of the breadth and scope of the present disclosure.

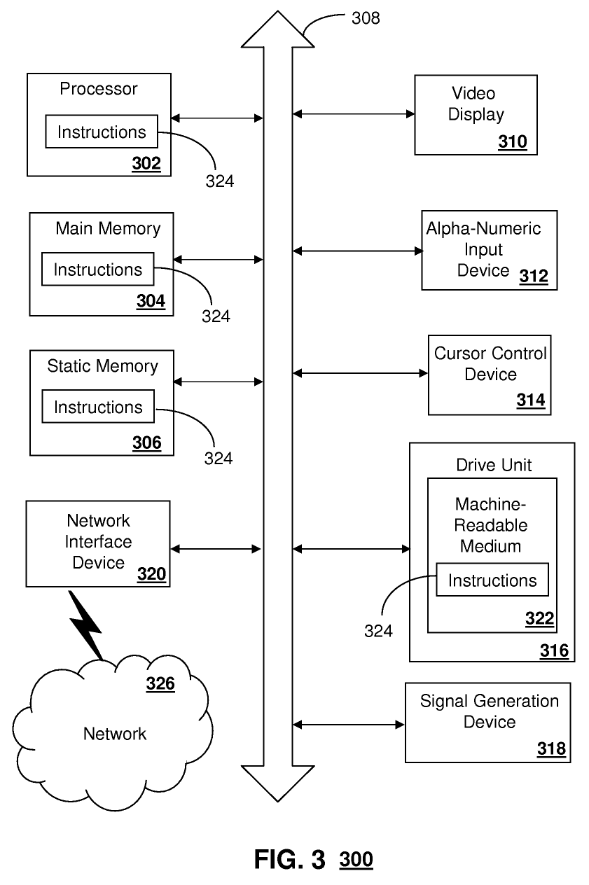

FIG. 3 depicts an exemplary diagrammatic representation of a machine in the form of a computer system 300 within which a set of instructions, when executed, may cause the machine to perform any one or more of the methodologies discussed above. In some embodiments, the machine operates as a standalone device. In some embodiments, the machine may be connected (e.g., using a network) to other machines. In a networked deployment, the machine may operate in the capacity of a server or a client user machine in server-client user network environment, or as a peer machine in a peer-to-peer (or distributed) network environment.

The machine may comprise a server computer, a client user computer, a personal computer (PC), a tablet PC, a laptop computer, a desktop computer, a control system, a network router, switch or bridge, or any machine capable of executing a set of instructions (sequential or otherwise) that specify actions to be taken by that machine. It will be understood that a device of the present disclosure includes broadly any electronic device that provides voice, video or data communication. Further, while a single machine is illustrated, the term “machine” shall also be taken to include any collection of machines that individually or jointly execute a set (or multiple sets) of instructions to perform any one or more of the methodologies discussed herein.

The computer system 300 may include a processor 302 (e.g., a central processing unit (CPU), a graphics processing unit (GPU, or both), a main memory 304 and a static memory 306, which communicate with each other via a bus 308. The computer system 300 may further include a video display unit 310 (e.g., a liquid crystal display (LCD), a flat panel, a solid state display, or a cathode ray tube (CRT)). The computer system 300 may include an input device 312 (e.g., a keyboard), a cursor control device 314 (e.g., a mouse), a disk drive unit 316, a signal generation device 318 (e.g., a speaker or remote control) and a network interface device 320.

The disk drive unit 316 may include a machine-readable medium 322 on which is stored one or more sets of instructions (e.g., software 324) embodying any one or more of the methodologies or functions described herein, including those methods illustrated above. The instructions 324 may also reside, completely or at least partially, within the main memory 304, the static memory 306, and/or within the processor 302 during execution thereof by the computer system 300. The main memory 304 and the processor 302 also may constitute machine-readable media.

Dedicated hardware implementations including, but not limited to, application specific integrated circuits, programmable logic arrays and other hardware devices can likewise be constructed to implement the methods described herein. Applications that may include the apparatus and systems of various embodiments broadly include a variety of electronic and computer systems. Some embodiments implement functions in two or more specific interconnected hardware modules or devices with related control and data signals communicated between and through the modules, or as portions of an application-specific integrated circuit. Thus, the example system is applicable to software, firmware, and hardware implementations.

In accordance with various embodiments of the present disclosure, the methods described herein are intended for operation as software programs running on a computer processor. Furthermore, software implementations can include, but not limited to, distributed processing or component/object distributed processing, parallel processing, or virtual machine processing can also be constructed to implement the methods described herein.

The present disclosure contemplates a machine readable medium containing instructions 324, or that which receives and executes instructions 324 from a propagated signal so that a device connected to a network environment 326 can send or receive voice, video or data, and to communicate over the network 326 using the instructions 324. The instructions 324 may further be transmitted or received over a network 326 via the network interface device 320.

While the machine-readable medium 322 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present disclosure.

The term “machine-readable medium” shall accordingly be taken to include, but not be limited to: solid-state memories such as a memory card or other package that houses one or more read-only (non-volatile) memories, random access memories, or other re-writable (volatile) memories; magneto-optical or optical medium such as a disk or tape; and carrier wave signals such as a signal embodying computer instructions in a transmission medium; and/or a digital file attachment to e-mail or other self-contained information archive or set of archives is considered a distribution medium equivalent to a tangible storage medium. Accordingly, the disclosure is considered to include any one or more of a machine-readable medium or a distribution medium, as listed herein and including art-recognized equivalents and successor media, in which the software implementations herein are stored.

Although the present specification describes components and functions implemented in the embodiments with reference to particular standards and protocols, the disclosure is not limited to such standards and protocols. Each of the standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same functions are considered equivalents.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments may be utilized and derived therefrom, such that structural and logical substitutions and changes may be made without departing from the scope of this disclosure. Figures are also merely representational and may not be drawn to scale. Certain proportions thereof may be exaggerated, while others may be minimized. Accordingly, the specification and drawings are to be regarded in an illustrative rather than a restrictive sense.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. A network proxy of a communication system, comprising a controller element to:
monitor for installed components in one or more interconnected Digital Subscriber Line (DSL) networks of the communication system based at least in part on provisioning records for each of the interconnected DSL networks;
obtain telemetry data from at least one of the installed components in the interconnected DSL networks;
obtain maintenance data based at least in part on repair records associated with the installed components in the interconnected DSL networks;
filter the telemetry and maintenance data according to criteria comprising actual criteria and predictive criteria;
determine one or more common components for the installed components associated with the filtered telemetry and maintenance data;
identify an actual fault in the one or more common components based at least in part on the filtered telemetry and maintenance data associated with the actual criteria; and
predict a potential fault in the one or more common components based at least in part on the filtered telemetry and maintenance data associated with the predictive criteria.

2. The network proxy of claim 1, wherein the controller element is configured to transmit the fault data to a service center based at least in part on at least one of an identification of an actual fault and a prediction of a potential fault.

3. The network proxy of claim 1, wherein the provisioning data comprises at least one among component identification data, component configuration data, component location data, and component interconnection data.

4. The network proxy of claim 1, wherein the telemetry data comprises at least one among metallic loop data and component performance data.

5. The network proxy of claim 4, wherein the component performance data comprises at least one among bit rate data, noise margin data, capacity data, attenuation data, latency data, and error data.

6. The network proxy of claim 1, wherein the maintenance data comprises at least one among data service repair data and voice service repair data.

7. The network proxy of claim 1, wherein the criteria comprises at least one among an error rate criteria, a bit rate criteria, and an attenuation value criteria.

8. The network proxy of claim 1, wherein the one or more common components comprises at least one among a service access interface (SAI), a feeder (F1) cable, a distribution F2 cable, a drop (F3) cable, and a serving terminal.

9. The network proxy of claim 1, wherein the controller element generates a message for at least one of the interconnected DSL networks that are associated with the one or more common components, the message including an identification of the one or more common components and the telemetry data and maintenance data associated with the one or more common components.

10. A network element coupled to one or more interconnected Digital Subscriber Line (DSL) networks of a communication system, the network element comprising a controller to:
receive fault data from a network proxy of the communication system, the fault data representative of a potential fault in a component of a plurality of components of the interconnected DSL networks; and
test the component for the potential fault based at least in part on telemetry data and maintenance data associated with the component, wherein the plurality of components is identified from provisioning records for each of the interconnected DSL networks, wherein the telemetry data is obtained from at least one of the plurality of components, and wherein the maintenance data is generated from repair records associated with the plurality of components.

11. The network element of claim 10, wherein the telemetry and maintenance data is filtered according to criteria comprising actual criteria and predictive criteria, and wherein the potential fault is determined based at least in part on the telemetry and maintenance data associated with the predictive criteria.

12. The network element of claim 10, wherein the controller validates a message transmitted by the network proxy to the interconnected DSL networks associated with the component, the messages including an identification of the component and the telemetry data and maintenance data associated with the component.

13. The network element of claim 10, wherein the controller generates a service ticket for maintenance of the component.

14. The network element of claim 13, wherein the controller updates at least one among a database of repair records and a database of provisioning records based at least in part on the service ticket.

15. A computer-readable storage medium in a maintenance server of a communication system, comprising computer instructions for:
monitoring for installed components in interconnected cable networks of the communication system based at least in part on provisioning records for each of the interconnected cable networks;
filtering telemetry and maintenance data associated with the installed components in the interconnected cable networks according to criteria comprising actual criteria and predictive criteria;
monitoring for a fault in the installed components based at least in part on the telemetry and maintenance data associated with the actual criteria; and
predicting a potential fault in the installed components based at least in part on the telemetry and maintenance data associated with the predictive criteria.

16. The storage medium of claim 15, comprising computer instructions for:
determining one or more common components associated with the telemetry and maintenance data; and
generating a report comprising identification for each of the one or more common components and at least a portion of the telemetry and maintenance data associated with each of the one or more common components.

17. The storage medium of claim 15, comprising computer instructions for transmitting fault data to a service center based at least in part on at least one of the fault and the potential fault.

18. The storage medium of claim 15, comprising computer instructions for:
retrieving the telemetry data from at least a portion of the installed components in the interconnected cable networks; and
generating the maintenance data based at least in part on repair records associated with the installed components in the interconnected cable networks.

19. The storage medium of claim 15, wherein the telemetry data comprises at least one among metallic loop data and component performance data.

20. The storage medium of claim 19, wherein the component performance data comprises at least one among bit rate data, noise margin data, capacity data, attenuation data, latency data, and error data.

21. The storage medium of claim 15, wherein the maintenance data comprises at least one among data service trouble ticket data and voice service trouble ticket data.

22. The storage medium of claim 15, wherein the criteria comprises at least one among an error rate criteria, a bit rate criteria, and an attenuation value criteria.

23. The storage medium of claim 15, wherein a cable network comprises at least one among a Digital Subscriber Line (DSL) network, a coaxial cable network, and a fiber cable network.

24. The storage medium of claim 15, wherein a fault comprises at least one among a bonding fault, a grounding fault, a metallic fault, a bridge tap fault, and an electromagnetic interference fault.
